(19) United States
(12) Patent Application Publication
(10) Pub. No.: US 2005/0090104 A1
(43) Pub. Date: Apr. 28, 2005

(54) Slurry compositions for chemical mechanical polishing of copper and barrier films

(76) Inventors: Kai Yang, Hsinchu (TW); Su-Man Tseng, Hsinchu (TW); Wes Jeng, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/958,417

(22) Filed: Oct. 6, 2004

Related U.S. Application Data
(60) Provisional application No. 60/514,830, filed on Oct. 27, 2003.

(51) Int. Cl. H01L 21/302; H01L 21/461

(52) U.S. Cl. 438/689

(57) ABSTRACT

CMP slurries comprising at least an abrasive, at least an organic phosphonate, at least an oxidizer, and water are disclosed. The slurries can optionally include corrosion inhibitors, surfactants, polymers, and bases. The concentrations of the ingredients in the slurries can be appropriately chosen to formulate copper CMP slurry and barrier CMP slurry. The copper CMP slurries are capable of polishing copper at high removal rate and having high selectivity to tantalum barrier. The barrier slurries deliver good planarity and have high hydrogen peroxide stability.

### REFERENCES TO RELATED APPLICATIONS

This Application is based on U.S. Provisional Application Ser. No. 60/514,830 filed on 17 Oct. 2003.

### FIELD OF THE INVENTION

The present invention relates to chemical mechanical polishing of metal for microelectronic application. The present invention is especially useful for polishing copper and barrier films to fabricate copper interconnect wiring through damascene process. More particularly, the present invention relates to the slurry compositions for chemical mechanical polishing (CMP) of copper and barrier film containing tantalum.

### DESCRIPTION OF THE PRIOR ART

Copper has lower resistivity and better electrimigration resistance than metals commonly used in microelectronics, such as aluminum and tungsten. Therefore, semiconductor integrated circuits (IC) with copper interconnect wiring provide higher speed performance and better reliability. Copper has become the preferred metal for interconnect wiring in semiconductor IC with feature size below 0.18 micron.

Because copper compounds generally have low vapor pressure, copper plasma etching process that can work at a temperature compatible to other semiconductor wafer processing is not currently available for copper patterning. Therefore, patterning of copper film in the IC fabrication is commonly conducted through a damascene process. For more detailed explanation of damascene process, please see U.S. Pat. No. 4,944,836.

Copper atom can readily diffuse into SiO₂ and other dielectric films and copper film has poor adhesion to SiO₂ and other dielectric film. To solve these problems, a refractory metal or its alloy, such as Ta, Ta, Ti, TiN, W, WN, etc. is needed as liner film between copper and the dielectric film to block copper diffusion and promote adhesion. The liner film is also commonly called “barrier film” in the semiconductor industry.

FIG. 1-4 briefly illustrate commonly adopted damascene fabrication process for copper interconnects wiring. The process consists of several phases. First, insulator films 10 such as silicon dioxide, silicon nitride, and/or other dielectrics are uniformly deposited, and then trenches 20 as well as trenches 21 with vias 22 are created in the insulator though photolithographic patterning and plasma etching, as shown in FIG. 1. Next, A barrier film 30 and a copper film 40 are deposited on the top of patterned dielectric film and fill the trenches 20, 21 and vias 22, as shown in FIG. 2. Afterward, the copper film and barrier film on the outside of trenches are sequentially removed away by chemical mechanical polishing, as shown in FIG. 3 and FIG. 4. The remaining copper and barrier film inlaid in trenches and vias form copper lines and plugs connecting metal layer underneath. The above procedures can be repeated to build multi-layer metal interconnects. Depending on the complexity of the IC, the number of metal layers ranges from two to more than ten.

As mentioned above, the CMP is an important part of damascene process flow in the copper interconnects fabrication. In order to achieve good planarity and good control over the conductor line thickness uniformity across the wafer, the CMP process is often conducted in two steps. In the first step, copper film on the outside of trench is polished away using a high copper to barrier selectivity slurry and the polishing stops on the barrier metal layer, as shown in FIG. 3. The first-step CMP will be herein termed as “copper CMP”. In the second step, the barrier film outside of trench as well as some amount of dielectric film and copper film are removed using a different slurry, which generally has a low removal rate selectivity among barrier, copper, and dielectric films. After the second-step polishing, the wafer surface is planarized as shown in FIG. 4. The second-step CMP will be herein termed as “barrier CMP”. It must be noted that the barrier CMP removes not only barrier film but also some amount of copper and dielectric film in order to achieve planarization. When a CMP polisher has more than three polishing platen, the copper CMP is often conducted in first and second platens and the barrier CMP is conducted in the third platen to maximize throughput.

The chemical compositions of slurries are critical to the performance of the copper and barrier CMP process. The slurries generally comprise abrasive, such as alumina and silica, oxidizing agent, complexing agent, and corrosion inhibitor in aqueous medium. The dispersed abrasive in the slurry provide mechanical abrasion action in the metal polishing. The oxidizing agent and complexing agent chemically attack metal film surface so that the polishing removal rate can be enhanced. The corrosion inhibitor, such as benzotriazole (BTA), passivates copper surface to prevent pitting and other types of corrosion defects.

U.S. Pat. No. 5,897,375 to Watts et al. and U.S. Pat. No. 6,001,730 to Farkas et al. teach a method for forming copper interconnects and disclose slurry compositions for polishing copper and barrier metal films using carboxylate salt. U.S. Pat. No. 6,083,840 to Mravic et al. disclose copper and barrier CMP slurry comprising carboxylic acids. U.S. Pat. Nos. 6,309,560 and 6,432,829 to Kaufman et al. disclose copper CMP slurry formulation comprising abrasive, urea hydrogen peroxide, tartaric acid and film forming agent. U.S. Pat. No. 6,316,365 to Wang et al. discloses copper and tantalum slurry using persulfate compounds. U.S. Pat. No. 6,303,049 to Lee et al. discloses slurry formulation comprising mixture of phosphorus acid, amino acid and carboxylic acid. U.S. Pat. No. 6,348,076 to Canaperi et al. discloses slurry formulation comprising an abrasive, an oxidizing agent, and polyelectrolyte.

In order to make IC with higher performance, the semiconductor industry starts employing low-k dielectric materials as insulator for the IC interconnects in 0.13 micron process technology and beyond. Low-k dielectric generally has low mechanical strength and relatively poor adhesion to other films in the IC. To prevent delamination of low-k dielectric films, scratches, and other defects during the CMP process, the down force used in the CMP must be kept low, typically less than 2 psi. Unfortunately, for many copper CMP slurries of prior art, the CMP removal rate decreases significantly at low down force, which leads to significant throughput reduction. Presently, copper CMP slurry that can provide high removal rate at low pressure is strongly needed.

As mentioned previously, the copper CMP slurry and barrier CMP slurry generally contain at least one oxidizer, such as hydrogen peroxide, ammonium persulfate, etc. The oxidizer can often react with carboxylic acid, amino acid, and other organic ingredients, causing short pot life and polishing performance instability. Hydrogen peroxide in the slurry can aslo decompose at fast rate when the slurry contains trace amount of metal, in particular transitional metal, such as iron and copper. The trace amount of transitional metal at concentration level of parts per million (ppm), is generally introduced into slurry from impurity in alumina or silica abrasive. The concentration of hydrogen peroxide affects the CMP removal rate, uniformity, and planarization capability. In order to have a stable CMP process, there is a strong need to have a CMP slurry that can keep the concentration of hydrogen peroxide and its other ingredients stable.

### SUMMARY OF THE INVENTION

An object of present invention is to provide copper CMP slurries that give high copper removal rates at a relatively low down force so that CMP throughput is improved and CMP defects are reduced.

A further object of the present invention is to provide copper and barrier CMP slurries in which hydrogen peroxide and other additive concentrations have good stability so that slurry pot lifetime is extended and the performance of CMP process is stable.

An additional object of present invention is to provide copper CMP slurries that give low dishing and erosion so that the interconnect metal lines have uniform sheet resistance and the wafer surface planarity is sufficiently good for fabrication multi-level interconnects.

Another object of present invention is to provide copper CMP slurries that have high removal-rate selectivity of copper to the barrier film containing tantalum.

Yet another object of present invention is to provide CMP slurry that can provide smooth copper surface on the polished surface.

Still yet another object of present invention is to provide CMP slurries that give low copper corrosion defects on polished wafers.

Still yet another object of the present invention is to provide slurries that are cost effective in manufacture.

In an embodiment of present invention, a copper CMP slurry consists of an abrasive, an oxidizer, an organic phosphonate, a corrosion inhibitor, and deionized water. In a preferred embodiment, the copper CMP slurry comprises from 0.05% to 3% of alumina abrasive, from 1 to 10% of hydrogen peroxide, from 0.05% to 5% of 1-hydroyethylidene-1,1-diphosphonic acid, from 0.02% to 1% benzotriazole, from 0.1 to 3% of polyvinylpyrrolidone with molecular weight of about 40,000, with alumina being dispersed and all other ingredients being dissolved in deionized water.

In another embodiment of present, a barrier CMP slurry comprises a silica abrasive, an oxidizer, an organic phosphonate, a corrosion inhibitor, a base, and deionized water. In a preferred embodiment, the slurry includes from 3% to 30% of colloidal silica abrasive, from 0.05% to 2% of hydrogen peroxide, from 0.01% to 1% of 1-hydroyethylidene-1,1-diphosphonic acid, 0.05% to 3% of potassium hydroxide, from 0.005% to 0.2% of benzotriazole, with silica being dispersed and all other ingredients being dissolved in deionized water.

### BRIEF DESCRIPTION OF THE DRAWINGS

FIG. 1-4 schematically illustrates sequential phases of a damascene process flow.

FIG. 1 shows a cross section of trenches and vias formed after lithographic patterning and etch.

FIG. 2 shows a cross section of barrier film and copper film deposited on a wafer surface with trenches and vias.

FIG. 3 shows a cross section of the wafer after copper CMP. The copper CMP removes copper film on the outside of trenches and stop on barrier film surface. There is some recess 41 in the copper line. The recess is usually referred as “dishing” in the semiconductor industry.

FIG. 4 shows a cross section of the wafer after barrier CMP. The barrier film on outside of trenches is removed. A small amount of dielectric film and copper film inside of trenches are also polished away, resulting in a very planar wafer surface.

FIG. 5 shows a cross section of the wafer after barrier CMP with a barrier CMP slurry that polishing dielectric film faster than copper film. The copper film protrudes on the wafer surface.

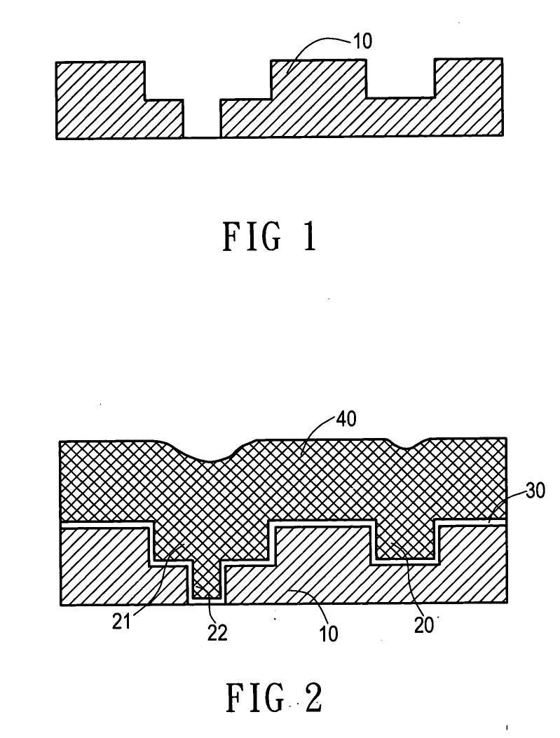

### DETAILED DESCRIPTION OF THE PREFERRED EMBODIMENT

Definition

The present invention is related to slurry compositions for copper and barrier CMP. Both copper and barrier CMP slurries of present invention comprise at least one organic phosphonate.

An organic phosphonate is an organic compound having at least one functional group illustrated as follows: 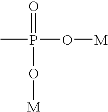
where M can be a hydrogen, ammonium, metal, or other cation ions. When all Ms in the function group are hydrogen atoms, the compound is said to be an organic phosphonate in acid form, or simply, phosphonic acid. When at least one of the two Ms in the functional group is not hydrogen but other cation, the compound is said to be an organic phosphonate in the salt form, or simply a phosphonate salt. Said metal can be potassium, sodium, magnesium, barium, etc. The phosphonate salts can be produced from the reaction of a phosphonic acid and a base as defined by G. N. Lewis. When there is only one such functional group in a molecule of an organic compound, the compound is called organic monophosphonate. When there are a plurality of such function groups in a molecule of a compound, the compound is often called organic polyphosphonate. The term “organic phosphonates” as used herein, include organic monophosphonates and polyphosphonates whether in the acid form or in salt form.

Examples of organic phosphonates are alkylphosphonic acid, phenylephosphonic acid (abbreviated as PPA), 1-hydroxyethylidene-1,1-diphosphonic acid (abbreviated as HEDP), aminotris (methylenephosphonic acid), Ethylene diamine tetra (methylene phosphonic acid), 2-phosphonobutane-1,2,4-tricaboxylic acid (abbreviated as PBTC), hexamethylenediaminetetra (metylenephosphonic acid), diethylenetriamine penta (methylenephonsporic acid), and salts theirof. Many of organic phosphonates are available from Solutia.

Copper CMP Slurry

As mentioned in the previous paragraphs, the goal of the copper CMP is to remove copper film outside of trenches. It is desirable to have a high removal rate in order to increase the throughput of the copper CMP process. The copper CMP slurries of the present invention comprise at least one organic phosphonate, at least one abrasive, and at least one oxidizer. Optionally, the copper CMP slurries of present invention can comprise at least one additional additive selected from the group consisting of corrosion inhibitors, bases, surfactants, polymers, carboxylic acids and salts thereof, and amino acids and salt thereof.

The organic phosphonate is presented in the copper CMP slurries of present invention in an amount ranging from 0.01 weight percent to 10 weight percent and preferably in an amount ranging from 0.1 weight percent to 2 weight percent.

Organic phosphonates are excellent chelating agents for copper. The slurries comprising organic phosphonates exhibit high copper polishing removal rates even at low down force. The advantage of having high polishing removal rate at low down force becomes more important when low-k dielectric films replaces silicon dioxide as insulators in the IC interconnects. Since low-k dielectrics are materials with relatively low mechanical strength and poor adhesion to other films in a IC, it requires CMP processes be conducted at low down force to prevent delamination, pits, and other types of damaging defects.

Although slurry comprising mineral acids, such as phosphoric acid, sulfuric acid, and nitric acid, can also give high CMP removal rate, the slurries comprising organic phosphonates generally show less corrosion on copper interconnects of the polished wafers.

The phosphonates generally have significantly higher solubility in water comparing to many carboxylic and amino acids or salts disclosed in the prior art for copper CMP. The manufacturing process of copper slurry comprising phosphonates is usually simpler and more cost effective.

The abrasive comprised in the copper CMP slurry of this invention can be alumina abrasive, silica abrasive, ceria, titanium oxide, zirconia, or mixtures thereof. The preferred abrasives are alumina and silica. In order to reduce scratch defects, the mean particle size of the abrasive must be less than 0.3 micron and the D90 of the abrasive must be less than 1 micron. D90 is a characteristic number given by a particle sizing instrument to indicate that the sizes of 90% of particles are less than the characteristic number. Preferably, the mean particle size is in between 0.02 and 0.15 micron and D90 is less than 0.3 micron.

The alumina abrasive can be in alpha, gamma, or theta phase. Generally, alpha phase alumina abrasive gives higher copper removal rate. An example of a typical alumina abrasive is APA alumina abrasive from Sosol North America Inc. The alumina abrasive must first be well deagglomerated and dispersed in water with a high-speed mixer or attritor. Then the alumina abrasive slurry must be filtered with a filter of 3 micron or less to remove large particles. The silica abrasive can be fumed silica abrasive or colloidal silica abrasive that are grown from a solution. An example of colloidal silica abrasive is silica abrasive from H.C. Starck under trade name Levasil.

If the abrasive concentration is too low, the removal rate reduces significantly and process becomes instable. If the abrasive concentration is too high, the removal rate selectivity to barrier film decreases and scratch defect density increases. The abrasive is presented in the copper slurry of this invention in an amount ranging from 0.01 to 10 weight percent and preferably in an amount ranging from 0.1 to 1 weight percent.

The oxidizer used in the present invention can be hydrogen peroxide, ammonium persulfate, potassium persulfate, ferric nitrate, potassium permaganate, potassium iodate, periodic acid, and mixture thereof. The concentration of oxidizer in the copper CMP slurry of the present invention is preferably in a range from 0.1 to 20% weight percent and preferably in an amount ranging from 1 to 10 weight percent. The preferred oxidizer is hydrogen peroxide. Hydrogen peroxide is generally supplied in 30 weight percent liquid for electronic industry. The hydrogen peroxide concentration given in this disclosure is the net hydrogen peroxide concentration.

Some of organic phosphonate solutions have a low pH value. Copper corrosion may occur when a slurry with low pH is used. To prevent copper corrosion, a base as in the definition of G. N. Lewis, such as ammonium hydroxide, potassium hydroxide, tetramethyl ammonium hydroxide, and ethylenediamine, can be added to the slurry to raise pH value. The preferred pH value of the copper slurries of the present invention ranges from 1.5 to 9, most preferably from 2.5 to 7.

Optionally, the copper CMP slurries of present invention may comprise a corrosion inhibitor or a combination of copper corrosion inhibitors in order to enhance corrosion resistance during CMP. The preferred copper inhibitors are compounds containing one or more azoles. Example of such copper corrosion inhibitors are benzotriazole, 1,2,4-triazole, tretrazole, tolytriazole, 4-carboxybenzotriazole, 5-carboxybenzotriale, mercaptobenzoxazole, 2-mercaptobenzothiazole, 2-mercaptobenzimidazole, and derivatives thereof. The most preferred corrosion inhibitors are benzotriazole and tolytriazole. Generally, the lower the pH of the slurry, the more corrosion inhibitor is required. The concentration of corrosion inhibitor in the copper CMP slurry of this invention can be in a range from 0 to 1 weight percent and preferably from 0.04 to 0.4 weight percent.

Additionally, the copper CMP slurries of the present invention may optionally comprise a surfactant or a combination of surfactants. Surfactants can improve surface smoothness of polished copper film and reduce defects. Surfactants can also improve the within-wafer uniformity of removal rate. Non-ionic, anionic, cationic, and Zwitterionic surfactants can all be used. Examples of surfactants that can be added to the slurry are given in the followings: (1) polyethylene glycol sorbitan monolaurate and other polyoxyethylene derivatives of sorbitan esters under trade name “Tween” from Uniqema; (2) polyethylene glycol octadecyl ether and other polyoxyethylene fatty ether under trade name “Brij” from Uniqema; (3) nonylphenol ethoxylates under trade name Tergitol from Dow Chemical; (4) octylphenol ethoxylates under trade name Triton X from Dow Chemical. (5) sodium lauryl sulfate and other surfactants of salts of alkyl sulfate; (6) sodium 1-dodecanesulfonate and other surfactants of salts of alkyl sulfonate. (7) quarternary ammonium salts. The preferred surfactants are polyoxyethylene derivatives of sorbitan esters and octylphenol ethoxylates. The surfactant concentration presented in the copper CMP slurry of this invention can be in a range from 0 to 1 weight percent and preferably from 0.01 to 0.2 weigh percent.

Further more, the copper CMP slurries of the present invention may optionally comprise a water-soluble polymer or a combination of water soluble polymers. The presence of polymers in the slurry promotes colloidal suspension of the abrasive particles and reduces surface roughness of polished copper film. Polymer molecules in the slurry coat the abrasive surface and wafer surface, making abrasion gentler during CMP. The employment of polymers in the slurries also improves removal rate selectivity between copper and Ta film. Examples of polymers are polyethylene glycol, polyvinyl alcohol, and polyvinyl pyrrolidone (PVP), polyacrylic acid, polymethaacrylic acid. The polymers used in the slurry of present invention have a molecular weight between 5000 and 1,000,000 daltons. The water solubility of a polymer generally decreases as its molecular weight increases. The preferred range of the polymer molecular weight is between 5000-100,000 daltons. The preferred polymer is polyvinyl pyrrolidone with the molecular weight from 5000-10,000 daltons. The polymer concentration presented in the copper CMP slurries of the present invention can be in a range from 0.01 to 5 weight percent and preferably from 0.05 to 1 weight percent.

Carboxyl acids, amino acids, and salts thereof can be used in combination with said organic phosphonates in the copper CMP slurry to tune the removal rate profile across the wafer and minimize the within-wafer non-uniformity. Examples of carboxyl acids and amino acids are formic acid, acetic acid, propionic acid, butyric acid, valeric acid, glycolic acid, lactic acid, glucoheptonic acid, gluconic acid, oxalic acid, malonic acid, malic acid, citric acid, tartaric acid, succinic acid, glutaric acid, adipic acid, pemelic acid, acrylic acid, maleic acid, glycine, alanine, aspartic acid, glutamic acid.

The copper CMP slurries of the present invention are typically used at down force from 0.3 to 5 psi and more typically from 0.5 to 2 psi. When the slurries are used in a rotary CMP polisher such as a Mirra polisher manufactured by Applied Materials, the platen rotation speed ranges from 20 to 150 rpm and preferably from 40 to 120 rpm. When the slurries are used in a linear polisher such as a Teres polisher manufactured by Lam Research, polishing belt runs at a linear speed ranging from 50 to 500 ft/min and preferably from 200 to 350 ft/min. The slurry flow rate ranges from 50 to 400 ml/min and preferably from 100 to 250 ml/min. The preferred polishing pads are polyurethane pads such as IC1000 pad manufactured by Rodel. Other polishing parameters can be set by those skilled in the art without exercising undue experimentation after reading the disclosure of this invention.

Using the copper CMP slurries of the present invention at polishing conditions described above, the CMP removal rate is in a range typically from 200 to 1200 nm/min and more typically from 300 to 700 nm/min. The present invention makes it possible to achieve a high copper CMP removal rate at low down force. For instance, the copper CMP removal rate of about 500 nm/min at 1 psi of down force and about 350 nm/min at 0.5 psi can be achieved with the slurry of the present invention. This advantage of the present invention becomes more important when low-k dielectrics materials are employed as insulator in the IC interconnects for the process technology of 0.13 micron and beyond.

The copper CMP slurries of the present invention are highly selective to copper with respect to barrier film containing tantalum. For instance, the selectivity can be higher than 200 when alumina abrasive is used. Accordingly, the polishing can completely stop at the surface of the barrier film.

When the point-of-use slurry filtration and other defect prevention measures commonly employed by those skilled in the art are taken, the compositions of present invention result in a low count of defects such as pitting, scratch, corrosion, and alike.

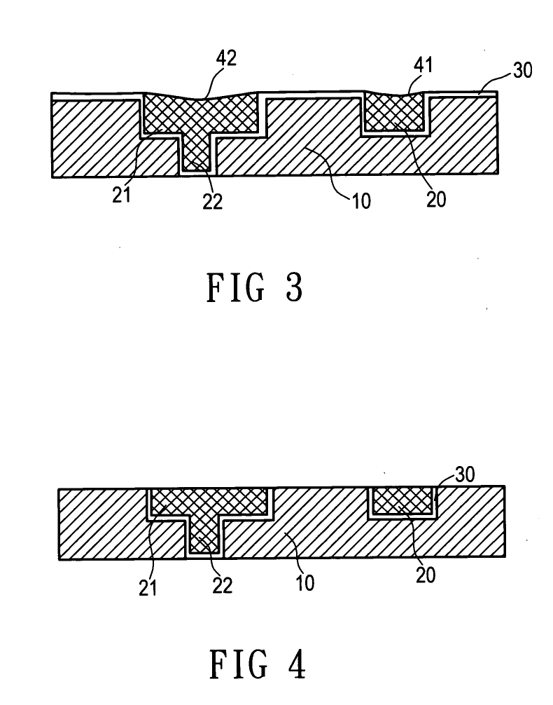

Dishing 41 and 42, as illustrated in FIG. 3, is the recess on copper line after CMP. Dishing negatively affects electrical resistance of copper line and manufacturability of subsequent metal layers of the IC interconnects. Therefore, it is desirable to reduce the amount of dishing to a level as low as possible. The copper CMP slurry of present invention can results in low dishing on copper lines. For example, dishing of less than 50 nm for 100 micron copper lines and dishing of less than 20 nm for 10 micron copper lines can be achieved with the slurries of the present invention.

The oxidizer is generally mixed with other ingredients of the slurry in a large container at a semiconductor fab and then the mixed slurry is delivered to CMP polishers. Because organic phosphonates are resistant to oxidation comparing to many of other copper chelating agents, the copper CMP slurries of present invention have long pot-life after mixing oxidizer with other ingredients of the slurry. For instance, the hydrogen peroxide concentration measured using the titration method with potassium permaganate and the organic phosphonate concentration measured using titration with sodium hydroxide show insignificant drop after mixing hydrogen peroxide with other ingredients of the slurry for one week. Accordingly, the CMP process shows a better stability over time.

The CMP slurries of the present invention will be further described by the examples in the later paragraphs of this disclosure.

Barrier CMP Slurry

The barrier CMP is responsible for removing barrier film outside of trenches and further planarizes wafer surface by also removing a small controlled amount of dielectric film and copper film. It is desirable to have low selectivity in removal rate for barrier, copper, and dielectric films.

The barrier CMP slurries of the present invention comprise silica abrasive, at least one organic phosphonate, and hydrogen peroxide, optionally a base and a copper corrosion inhibitor.

The silica abrasive can be fumed silica and colloidal silica, preferably, colloidal silica. Colloidal silica abrasives are grown from solution. The average size of abrasive ranges from 10 to 1000 nm, preferably from 20 to 100 nm, and most preferably from 30 to 60 nm.

The organic phosphonates that can be used for the barrier CMP slurries are similar to those used in the copper CMP slurries, but at significantly lower concentration. The concentration of organic phosphonates in the barrier CMP slurry ranges from 10 ppm to 1%, preferably from 50 ppm to 0.2%. The preferred organic phosphonate is 1-hydroxyethylidene-1,1-diphosphonic acid.

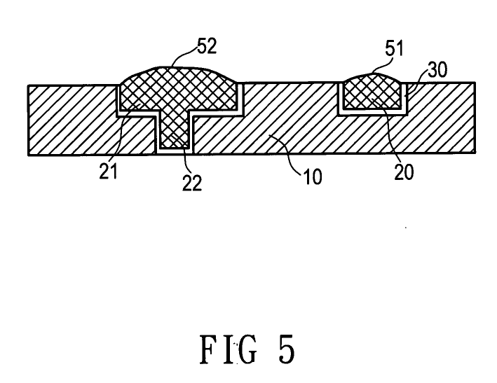

The organic phosphonates in the barrier CMP slurry improve tantalum barrier removal rate as well as copper removal rate so that the appropriate removal rate selectivity for tantalum, copper, and dielectric films can be achieved. The wafer polished with the barrier CMP slurry of present invention showed reduction of dishing comparing to the wafer right after copper CMP, while no copper protrusion occurs. As illustrate in FIG. 5, copper protrusion, sometimes also termed anti-dishing, refers to the situation when the top surface 51 of a copper line 20 is higher than the surface of dielectric film after CMP. Copper protrusion occurs when CMP removal rate of dielectric is significantly higher than that of copper. It is desirable to have no or low copper protrusion. High copper protrusion can increase electrical leakage between copper lines and cause copper residue in the subsequent meal layer. If the organic phosphonate concentration is too high in the barrier CMP slurry, the copper removal rate will be too high and can deteriorate dishing, which causes increase of metal line thickness variation. Therefore, the phosphonate concentration in the barrier CMP slurry must be optimized to achieve best planarity.

The concentration of hydrogen peroxide in the barrier CMP slurry ranges from 0.05 to 3 weight percent, preferably from 0.1 to 0.6 weight percent.

Optionally, the barrier CMP slurry of present invention may comprise a base or a combination of bases for pH adjustment. The pH of the barrier CMP slurry can be in the range from 3 to 12, preferably from 7 to 11, most preferably, from 8.5 to 10.

To enhance corrosion resistance, the barrier CMP slurries of the present invention may comprise a corrosion inhibitor or a combination of corrosion inhibitors. The preferred copper inhibitors are compounds containing one or more azoles. Example of such copper corrosion inhibitors are benzotriazole, 1,2,4-triazole, tretrazole, tolytriazole, 4-carboxybenzotriazole, 5-carboxybenzotriale, mercaptobenzoxazole, 2-mercaptobenzothiazole, 2-mercaptobenzimidazole, and derivative theirof. The most preferred corrosion inhibitor is benzotriazole. Excess benzotriazole in the barrier CMP slurry can cause precipitation of copper-benzotriazole compounds on the wafer surface, leading to higher defect density. The concentration of benzotriazole can be in the range from 0 to 0.3 weight percent, preferably from 0.01 to 0.05 weight percent.

The organic phosphonates in the barrier CMP slurries of present invention can help to stabilize hydrogen peroxide. Trace amount of transitional metal impurities are usually present in the silica abrasive. The transitional metal ions in the slurry can catalyze the decomposition of hydrogen peroxide. Organic phosphonates are excellent chealating agent for these transitional metal ions and therefore they can reduce hydrogen peroxide decay rate. The organic phosphonates themselves are generally resistant to the oxidation by hydrogen peroxide. As such, the barrier CMP slurries of present invention have significantly longer pot life. For instance, hydrogen peroxide concentration and pH are stable for more one than one month after mixing hydrogen peroxide with the rest of components of the slurry.

The present invention of the barrier CMP slurries will be further described by the examples in the later paragraphs of this disclosure.

### EXAMPLES 1-15 AND COMPARATIVE EXAMPLES 1-3

Examples 1-15, as listed in Table 1, are some of preferred embodiments of the present invention for copper CMP slurries.

CMP test of the slurry performance was carried out using a Strasbaugh 6DS-SP polisher. The platen rotation speed was at 100 rpm and wafer carrier rotation speed was at 93 rpm. The slurry flow rate was 200 ml/min. Down force was 3 psi. Typical polishing time is 60 seconds for removal rate test. Polishing pad was IC-1000 from Rodel.

Blanket copper film with thickness of about 1 micron to 2 micron and blanket tantalum film with thickness of about 100 nm on 8-inch wafers were used for polishing removal rate and non-uniformity test. Patterned wafers with tantalum barrier thickness of about 30 nm and electroplated copper film thickness of about 1 micron deposited on trench depth of about 0.6 micron were used for planarization studies.

The metal film thickness was measured by a Prometrix RS-55. Prometrix is an instrument capable of measuring metal sheet resistance using a four-point probe. The metal thickness is obtained from the sheet resistance by assuming the electrical resisistivity of copper film is 1.8 μΩcm and electrical resistivity of tantalum film is 200 μΩcm. The removal thickness is difference between pre-polishing metal thickness and post-polishing metal thickness. The removal rate is the ratio of removal thickness and polishing time. The Prometrix RS-55 measures 49 points on a wafer. The non-uniformity is defined as the ratio of standard deviation of removal thickness at 49 points to the average of removal thickness at 49 points. The dishing is measured by a Tencor P-20 profiler. The dishing on 100×100 μm² bonding pad was measured for comparison of planarization capability of the slurries.

Examples 1-10 in Table 1 employed alumina as abrasive, hydrogen peroxide as oxidizer, and Tween 20 as surfactant, and three different organic phosphonates as complexing agents. All ten slurries showed high CMP removal rate and no corrosion was observed on the polished wafers. The non-uniformities of removal rates for all these slurries are less than 7%. It is evident from the examples that organic phosphonates even at concentration of no more than one weight percent are capable of delivering high CMP removal rate.

Example 11 comprising silica as abrasive, HEDP as complexing agent, hydrogen peroxide as oxidizer, and benzotriazole as corrosion inhibitor, exhibited high removal rate but slightly rough surface. In examples 12-15, pyrrolidone was included into slurries and polished wafers showed excellent copper surface quality.

To show the advantages of the present invention, three comparative examples, as 1C, 2C, and 3C, are also listed in Table 1. Slurries in the three examples comprised respectively citric acid, oxalic acid, and phosphoric acid, which had been disclosed in the prior art, showed significantly lower removal rate and high dishing. After comparing examples 1-15 to the three comparative examples 1C-3C, it become obvious that present invention by employing organic phosphonates as complexing agent in the copper CMP slurry has significant advantage over the prior art.

TABLE 1

| Slurry | Abrasive | Acid | H₂O₂ | Surfactant | Polymer | BTA | Cu rate | Dishing | Surface |
|---|---|---|---|---|---|---|---|---|---|
| No. | (wt %) | (wt %) | (wt %) | (wt %) | (wt %) | (wt %) | (nm/min) | (nm) | Condition |
| 1 | Al₂O₃ | PPA 1 | 1.7 | Tween 20 | | 0 | 501 | | smooth |
| | 0.3 | | | 0.01 | | | | | |
| 2 | Al₂O₃ | PPA 1 | 3.4 | Tween 20 | | 0 | 825 | | rough |
| | 0.3 | | | 0.01 | | | | | |
| 3 | Al₂O₃ | PPA 1 | 3.4 | Tween 20 | | 0.01 | 532 | 60 | smooth |
| | 0.3 | | | 0.01 | | | | | |
| 4 | Al₂O₃ | HEDP | 1.7 | Tween 20 | | 0 | 1119 | 85 | rough |
| | 0.3 | 0.3 | | 0.01 | | | | | |
| 5 | Al₂O₃ | HEDP | 1.7 | Tween 20 | | 0.1 | 953 | 80 | smooth |
| | 0.3 | 0.3 | | 0.01 | | | | | |
| 6 | Al₂O₃ | HEDP | 1.7 | Tween 20 | | 0.15 | 797 | | smooth |
| | 0.3 | 0.3 | | 0.01 | | | | | |
| 7 | Al₂O₃ | HEDP | 1.7 | Tween 20 | | 0.2 | 740 | 49 | smooth |
| | 0.3 | 0.3 | | 0.01 | | | | | |
| 8 | Al₂O₃ | HEDP | 3.4 | Tween 20 | | 0.2 | 913 | | smooth |
| | 0.3 | 0.3 | | 0.01 | | | | | |
| 9 | Al₂O₃ | PBTC | 1.7 | Tween 20 | | 0 | 591 | | smooth |
| | 0.3 | 0.25 | | 0.01 | | | | | |
| 10 | Al₂O₃ | PBTC | 1.7 | Tween 20 | | 0 | 966 | | rough |
| | 0.3 | 0.5 | | 0.01 | | | | | |
| 11 | SiO₂ | HEDP | 1.7 | | | 0.2 | 823 | | slightly rough |
| | 0.25 | 0.3 | | | | | | | |
| 12 | SiO₂ | HEDP | 1.7 | | PVP | 0.2 | 608 | 60 | smooth |
| | 0.25 | 0.3 | | | 0.4 | | | | |
| 13 | SiO₂ | HEDP | 1.7 | | PVP | 0.2 | 730 | 65 | smooth |
| | 0.75 | 0.3 | | | 0.4 | | | | |
| 14 | SiO₂ | HEDP | 2 | | PVP | 0.2 | 534 | 65 | smooth |
| | 0.25 | 0.15 | | | 0.4 | | | | |
| 15 | SiO₂ | HEDP | 3.4 | | PVP | 0.2 | 739 | 110 | smooth |
| | 0.25 | 0.15 | | | 0.4 | | | | |
| 1C | Al₂O₃ | citric acid | 1.7 | | | 0.2 | 317 | 140 | slightly rough |
| | 0.3 | 0.5 | | | | | | | |
| 2C | Al₂O₃ | phosphoric acid | 3.4 | | | 0.2 | 528 | 125 | corrosion |
| | 0.5 | 1 | | | | | | | |
| 3C | SiO₂ | oxalic acid | 1.7 | | | 0.2 | 183 | 120 | smooth |
| | 0.5 | 0.5 | | | | | | | |

Table 2 lists copper removal rate at different down forces using slurry from Example 7. Table 2 shows that the removal rate doe not obey Preston's law, namely, the removal rate is not linear with down force. Removal rate of higher than 350 nm/min can be achieved with the slurry of present invention even at very low down force, such as 0.5 psi. The property of high removal rate at low down force is particularly useful when dielectric film with dielectric constant of less that 2.5 is employed as electrical insulator in the IC interconnects.

TABLE 2

| Down Force | Cu rate | Ta rate |
|---|---|---|
| (psi) | (nm/min) | (nm/min) |
| 3 | 740 | 4.2 |
| 2 | 668 | 3.1 |
| 1 | 493 | 1.8 |
| 0.5 | 354 | 1.1 |

### EXAMPLES 16 AND 17 AND COMPARATIVE EXAMPLE 4C AND 5C

Table 3 lists examples 16 and 17 and comparative examples 4C and 5C. All four slurries listed in Table 3 comprised 15 weight percent of colloidal silica with average particles size of about 40 nm, 0.02 weight percent of benzotriazole, 0.33 weight percent of hydrogen peroxide, and water. Slurries of example 16 and 17 additionally comprised HEDP. Slurry of comparative example 5C additionally comprised propionic acid, which had been disclosed in the prior art. The pH of all four slurries was adjusted to 9.2 using potassium hydroxide.

The CMP test was conducted using similar conditions used in example 1-15 except that polishing pad was Polytex from Rodel and down force was two psi. By comparing examples 16 and 17 to comparative example 4C, it clear that the addition of small amount of HEDP into the barrier CMP slurry increases removal rate for copper, tantalum barrier as well as silicon dioxide and eliminates anti-dishing.

Although propionic acid can also perform similar function, HEDP has advantage of stabilize hydrogen peroxide better than propionic acid as evidenced in Table 4. The hydrogen peroxide concentration in the slurry was measured by titration method using potassium permanganate. The hydrogen peroxide decomposition rate is significantly lower for slurries comprising HEDP.

TABLE 3

| Slurry | Additive | Concentration | Cu rate | Ta rate | SiO₂ rate | |
|---|---|---|---|---|---|---|
| No. | acid | (wt %) | (nm/min) | (nm/min) | (nm/min) | Planarity |
| 20 | HEDP | 0.1 | 76 | 84 | 72 | Dishing ˜30 nm |
| 21 | HEDP | 0.05 | 49 | 81 | 71 | Dishing ˜16 nm |
| 4C | None | None | 8 | 72 | 68 | Anti-dishing ˜41 nm |
| 5C | Propionic acid | 0.1 | 52 | 67 | 75 | Dishing ˜18 nm |

TABLE 4

| Slurry | Hydrogen Peroxide Concentration (wt %) | | | | | |
|---|---|---|---|---|---|---|
| No. | 0 day | 3 days | 7 days | 14 day | 21 days | 28 days |
| 20 | 0.34 | 0.33 | 0.33 | 0.33 | 0.31 | 0.31 |
| 21 | 0.34 | 0.33 | 0.33 | 0.32 | 0.31 | 0.31 |
| 4C | 0.32 | 0.23 | 0.18 | 0.10 | 0.07 | |
| 5C | 0.33 | 0.28 | 0.24 | 0.21 | 0.19 | 0.17 |

It should be understood that copper mentioned in the previous paragraphs not only refers to pure copper but also includes copper alloys. It should also be understood that the barrier film mentioned in previous paragraphs can be a tantalum film, tantalum nitride film, other tantalum-containing film, or stacked films thereof.

The foregoing descriptions and examples describe and show only the preferred embodiments of the present invention. It is to be understood that the invention is capable of use in various other combinations and modifications within the scope of the inventive concept as expressed herein. Accordingly, the description is not intended to limit the invention to the form disclosed herein. Many other varied embodiments incorporating the teachings of the invention by those skilled in the art may fall within the scope of the present invention as claimed below.

1. A chemical mechanical polishing slurry comprising:
(1) at least one abrasive,
(2) at least one organic phosphonate,
(3) at least one oxidizer, and
(4) water.

2. The slurry of claim 1, wherein said abrasive is selected from the metal oxide group consisting of alumina, silica, titania, ceria, and mixtures thereof.

3. The slurry of claim 2, wherein said alumina is selected from the group consisting of alpha alumina, theta alumina, delta alumina, gamma alumina, and mixture thereof.

4. The slurry of claim 2, wherein said silica is selected from the group consisting of fumed silica, colloidal silica grown from solution, and mixture thereof.

5. The slurry of claim 1, wherein said abrasive particle has an average size in the range from 20 nm to 500 nm.

6. The slurry of claim 1, wherein said abrasive is present in the amount of 0.05 to 5 weight percent for using in said copper CMP.

7. The slurry of claim 1, wherein said abrasive is silica abrasive and said silica abrasive is present in the amount of 1 to 30 weight percent for using in said barrier CMP.

8. The slurry of claim 1, wherein said organic phosphonate is selected from alkylphosphonic acid, benzenephosphonic acid, 1-hydroxyethylidene-1,1-diphosphonic acid, aminotris (methylenephosphonic acid), Ethylene diamine tetra (methylene phosphonic acid), phosphonobutane-1,2,4-tricaboxylic acid, Hexamethylenediaminetetra (metylenephosphonic acid), diethylenetriamine penta (methylenephonsphonic acid), salts thereof, and mixture thereof.

9. The slurry of claim 1, wherein said organic phosphonate is present in the amount of 0.05 to 3 weight percent for using in said copper CMP.

10. The slurry of claim 1, wherein said organic phosphonate is present in the amount of 0.005 to 0.5 weight percent for using in said barrier CMP.

11. The slurry of claim 1, wherein said oxidizer is selected from group consisting of hydrogen peroxide, ammonium persulfate, potassium persulfate, ferric nitrate, potassium permaganate, potassium iodate, periodic acid, and mixture thereof.

12. The slurry of claim 1, wherein said oxidizer is hydrogen peroxide and it is present in the amount of 0.1 to 10 weight percent.

13. The slurry of claim 1, further comprising at least one additional additive, said additive is selected from the group consisting of corrosion inhibitors, surfactants, polymers, carboxylic acids, and amino acids, and bases.

14. The slurry of claim 13, wherein said corrosion inhibitors are benzotriazole, 1,2,4-triazole, tetrazole, tolytriazole, 4-carboxybenzotriazole, 5-carboxybenzotriale, mercaptobenzoxazole, 2-mercaptobenzothiazole, 2-mercaptobenzimidazole, derivative thereof, and mixture thereof.

15. The slurry of claim 13, wherein said corrosion inhibitors are present in a total amount of no more than two weight percent.

16. The slurry of claim 13, wherein said surfactants are nonionic, anionic, cationic, zwitterionic surfactants, and mixture thereof.

17. The slurry of claim 13, wherein said surfactants are present in a total amount of no more than one weight percent.

18. The slurry of claim 13, wherein said surfactants are polyoxyethylene derivatives of sorbitan esters, polyoxyethylene fatty ether, nonylphenol ethoxylates, octylphenol ethoxylates, salts of alkyl sulfate, salts of alkyl sulfonate, quaternary ammonium salts.

19. The slurry of claim 13, wherein said polymers are polyvinyl pyrrolidone, polyethylene glycol, and polyvinyl alcohol.

20. The slurry of claim 13, wherein said polymers have a molecular weight between 5000 and 1,000,000 daltons, and wherein said polymers are present in a total amount of no more than 5 weight percent.

21. The slurry of claim 13, wherein said carboxylic acids and salts thereof are acetic acid, glycolic acid, lactic acid, propionic acid, butyric acid, isobutyric acid, valeric acid, gluconic acid, benzoic acid, oxalic acid, malonic acid, succinic acid, glutaric acid, adipic acid, pimelic acid, malic acid, tartaric acid, citric acid, EDTA, maleic acid, phthalic acid, gallic acid, and salts thereof.

22. The slurry of claim 13, wherein said carboxylic acids are present in a total amount of less than three weight percent.

23. The slurry of claim 13, wherein said amino acids are glycine, alanine, isoleucine, 2-amino-n-butyric aicd, leucine, norvalin, aspartic acid, glutamic acid, glutamine, cystine, argineine, histidine, lysine, methionine, proline, serine, threonine, tyrosine, aminobenzoic acid, triptophan, tyrosine, optical isomer thereof, salts thereof, and derivative thereof.

24. The slurry of claim 13, wherein said amino acids are present in an amount of less than three weight percent.

25. The slurry of claim 13, wherein said bases are potassium hydroxide, sodium hydroxide, ammonium hydroxide, tetramethyl ammonium hydroxide, ethylenediamine and mixture thereof.

26. The slurry of claim 1, wherin the pH of said slurry is in the range from 1.5 to 9 when said slurry is used for said copper CMP.

27. The slurry of claim 1, wherein the pH of said slurry is in the range from 4 to 11 when said slurry is used for said barrier CMP.

28. The slurry of claim 1, wherein the polishing carried out using down force of about 0.3 psi to 3 psi.

29. The slurry of claim 1, wherein the components of said slurry are grouped into two or more parts and said parts are shipped in separated containers to a semiconductor wafer fabrication facility where all said parts are mixed before being used for polishing.
